(19) United States
(12) Patent Application Publication
(10) Pub. No.: US 2026/0065946 A1
(43) Pub. Date: Mar. 5, 2026

(54) MEMORY DEVICES WITH REDUCED NUMBER OF FRONTSIDE POWER TRACKS AND METHODS FOR MANUFACTURING THE SAME

(71) Applicant: Taiwan Semiconductor Manufacturing Company, Ltd., Hsinchu (TW)

(72) Inventors: Chia-Cheng Chen, Hsinchu City (TW); Ching-Wei Wu, Hsinchu City (TW)

(73) Assignee: Taiwan Semiconductor Manufacturing Company, Ltd., Hsinchu (TW)

(21) Appl. No.: 18/990,713

(22) Filed: Dec. 20, 2024

Related U.S. Application Data
(60) Provisional application No. 63/690,012, filed on Sep. 3, 2024.

(51) Int. Cl. G11C 5/06; H10B 10/00

(52) U.S. Cl. CPC G11C 5/06; H10B 10/18

(57) ABSTRACT

A memory device includes memory cells formed on a first side of a substrate and powered by a supply voltage; a third metallization layer formed on the first side and including third metal tracks, at least one of the third metal tracks configured to only carry a non-power signal instead of carrying the supply voltage; a fourth metallization layer formed on the first side and including fourth metal tracks, each configured only as a word line; a fifth metallization layer formed on a second side of the substrate and including fifth metal tracks, each configured to carry the supply voltage or a ground voltage; and a sixth metallization layer formed on the second side and including sixth metal tracks, each configured to carry the supply voltage or the ground voltage.

### CROSS-REFERENCE TO RELATED APPLICATION

This application claims priority to and the benefit of U.S. Provisional Application No. 63/690,012, filed Sep. 3, 2024, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory device, in accordance with some embodiments.

FIG. 2 illustrates an example circuit diagram of one memory cell of the memory device of FIG. 1, in accordance with some embodiments.

FIG. 3A and FIG. 3B collectively illustrate an example layout configured for forming the memory device of FIG. 1, in accordance with some embodiments.

FIG. 4A and FIG. 4B collectively illustrate another example layout configured for forming the memory device of FIG. 1, in accordance with some embodiments.

FIG. 5A and FIG. 5B collectively illustrate yet another example layout configured for forming the memory device of FIG. 1, in accordance with some embodiments.

FIG. 6 illustrates an example layout of the memory cell of FIG. 2, in accordance with some embodiments.

FIG. 7 illustrates a flow chart of an example method for fabricating the memory device of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Static random access memory (SRAM) is a type of volatile semiconductor memory device that includes multiple SRAM cells configured to respectively store data bits using bistable circuitry without refreshing. An SRAM cell, which is typically referred to as a bit cell, stores one bit of information, represented by the logic state of two cross coupled inverters. A plural number of these bit cells are generally formed as a memory array with rows and columns. Each bit cell in a memory array typically includes connections to a supply voltage and to a reference (e.g., ground) voltage. Logic signals on bit lines control reading from and writing to a bit cell, with a word line controlling connections of the bit lines to the inverters, which otherwise float. A word line may be coupled to the bit cells in a row of a memory array, with different word lines provided for different rows. A pair of bit lines may be coupled to each column of bit cells.

For a read operation at a bit cell, the corresponding bit lines may be pre-charged high (e.g., to a logic value ‘1’), and the corresponding word line may be asserted. The resulting values at the bit lines may correspond to the logic value of the bit of information stored at the bit cell. To write a ‘1’ into a bit cell, one of the corresponding bit lines, which may be denoted BL (which may stand for “bit line”), may be set to ‘1’ and the other bit line, which may be denoted BLB (which may stand for “bit line bar”), may be set to ‘0,’ and the word line may be asserted. To write a logical low value, BL and BLB may instead be set to ‘0’ and ‘1,’ respectively, and the word line may be asserted. The pair of bit lines BL, BLB may be referred to as a pair of complementary bit lines. It is understood nonetheless that the values at BL and BLB need not be logical complements of one another, e.g., as in the read operation described above, where BL and BLB are both set to ‘1.’

To improve memory access performance (e.g., write operation), dual rail power supply techniques have been proposed. In a dual rail power supply approach, with a first supply voltage (e.g., VDD) provided to power a peripheral circuit configured to control the bit cells, a second supply voltage (e.g., VDDM) may be provided to power the bit cells. The existing memory devices are constrained to have both of these supply voltages (VDD and VDDM) carried by metal tracks formed on the frontside of a substrate. For example, a number of first metal tracks formed in a first frontside metallization layer are configured to carry the first supply voltage (VDD), and a number of second metal tracks formed in a second frontside metallization layer are configured to carry the second supply voltage (VDDM). Such a constraint disadvantageously impacts the flexibility for metal routing on the frontside, while following the scaling trend to have an increased number of bit cells over a given area. Thus, it is understood that the existing memory devices have not been entirely satisfactory in certain aspects.

The present disclosure provides various embodiments of a memory device with a reduced number of frontside metal tracks that are configured to carry a supply voltage or a ground voltage. In various embodiments, the memory device, as disclosed herein, includes a memory array and a peripheral circuit operatively coupled to each other. The memory array includes a plural number of memory cells. The peripheral circuit is configured to operate or control the memory array, which may include various circuit components such as, for example, a driver circuit, an input/output circuit, etc. Each of the memory cells can be operatively formed by a plural number of first transistors, and the peripheral circuit can be operatively formed by a plural number of second transistors. Theses first/second transistors can be formed along a major surface on the frontside of a substrate. In some embodiments, the peripheral circuit can be powered by a first supply voltage (sometimes referred to as VDD), and the memory cells can be powered by a second supply voltage (sometimes referred to as VDDM).

Different from the existing memory device, the disclosed memory device can include a number of first metal tracks formed on the frontside and a number of second metal tracks formed on the backside of the substrate. By relocating some of the metal tracks from the frontside to the backside that are configured to carry the second supply voltage VDDM, a significant amount of real estate for metal routing on the frontside of the substrate can be released. This can advantageously reduce the capacitance coupling among the frontside metal tracks configured as word lines of the memory array. Further, a number of third metal tracks carrying the ground voltage, which, in the existing memory devices, are constrained to be placed on the frontside and in the same metallization layer as the word lines, can be relocated to the backside in the currently disclosed memory device. With these metal tracks relocated to the backside, the word lines can be formed to have a wider width, which can advantageously reduce a resistance of those word lines. Consequently, various performance characteristics (e.g., speed, maximum frequency, etc.) of the disclosed memory device can be greatly improved.

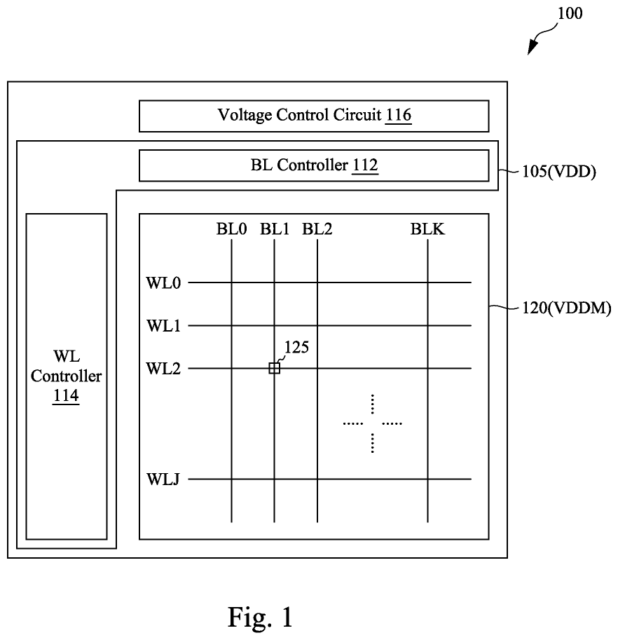

FIG. 1 illustrates a block diagram of a memory system, circuit, or device 100, in accordance with various embodiments. The memory device 100 is implemented as an integrated circuit. As shown in the illustrative example of FIG. 1, the memory device 100 includes a memory controller 105, a memory array 120, and optionally a voltage control circuit 116. The memory array 120 may include a number of storage circuits, memory cells, memory bits, or bit cells 125 arranged in two-dimensional or three-dimensional arrays. Each of the memory cells 125 is accessible through a plural number of access lines (e.g., one or more bit lines BLs and at least one word line WL). The memory controller 105 is operatively coupled to the memory array 120 so as to control operations (e.g., read operation, write operation) of the memory array 120. The memory controller 105 is sometimes referred to as a peripheral circuit with respect to the memory array 120.

The memory array 120 is a hardware component that stores data. For example, the memory array 120 is embodied as a semiconductor memory device. The memory array 120 generally includes a plural number of the storage circuits or memory cells 125, each of which is configured to store at least one data bit. In some embodiments, the memory array 120 includes word lines WL₀, WL₁ . . . WL_{J}, each extending in a first direction and bit lines BL₀, BL₁ . . . BL_{K}, each extending in a second direction. The word lines WL and the bit lines BLs may each be formed as one or more metal tracks or conductive rails. Each memory cell 125 is operatively connected to at least one corresponding word line WL and at least one pair of corresponding bit lines BLs (e.g., each memory cell 125 formed at an intersection of the corresponding word line WL and the corresponding pair of bit lines BLs), and can be operated according to voltages or currents through the corresponding word line WL and the corresponding bit lines BLs.

Each memory cell 125 may include a Static Random Access Memory (SRAM) cell. In one embodiment, the memory cell can be implanted as a six-transistor (6T) SRAM cell or otherwise single-port SRAM cell. In another embodiment, the memory cell 125 can be implemented as a seven-transistor (7T) SRAM cell or otherwise two-port SRAM cell. In yet another embodiment, the memory cell 125 can be implemented as an eight-transistor (8T) SRAM cell or otherwise three-port SRAM cell. However, it should be understood that the memory cell 125 can be implemented in any of various other memory configurations, while remaining within the scope of the present disclosure.

The memory controller 105 is a hardware component that is configured to control operations of the memory array 120. In some embodiments, the memory controller 105 includes at least a bit line controller 112 and a word line controller 114. In various embodiments of the present disclosure, each of the circuit components of the memory controller 105 may be powered by a first supply voltage (herein referred to as “VDD”), and the memory array 120 may be powered by a second supply voltage (herein referred to as “VDDM”). The first supply voltage VDD may be different from the second supply voltage VDDM.

For example, the word line controller 114 and the bit line controller 112 may be each powered by the VDD. The word line controller 114 can be configured to provide a voltage or current signal to one or more of the word lines WL. The bit line controller 112 can be configured to provide a voltage or current signal to one or more of the bit lines BLs. The bit line controller 112 may further include one or more input/output circuits (e.g., sense amplifiers, latches, etc.) configured to sense a voltage or current signal read from the memory array 120 through the one or more bit lines BLs. Although not shown, it should be understood that the memory controller 105 can include other circuit components to perform suitable memory operations such as, for example, an address decoder, an error correction circuit, a clock generator, etc.

The bit line controller 112 may be connected to the bit lines BLs of the memory array 120, and the word line controller 114 may be connected to the word lines WLs of the memory array 120. In general, to write a data bit to a memory cell 125, the word line controller 114 is configured to apply a voltage or current signal (sometimes referred to as a WL signal) on a corresponding word line WL, and the bit line controller 112 is configured to apply a voltage or current signal corresponding to the data bit to be stored to the memory cell 125 on one of the corresponding pair of bit lines BLs. To read the data bit from a memory cell 125, the word line controller 114 is configured to apply a WL signal on the corresponding word line WL, and the bit line controller 112 is configured to sense a voltage or current signal, corresponding to the data bit stored by the memory cell 125, that is present on the corresponding bit line BL. In some other embodiments, the memory controller 105 can include more, fewer, or different components than shown in FIG. 1, while remaining within the scope of the present disclosure.

The voltage control circuit 116 is a hardware component configured to control power supplied to the memory array 120 and power supplied to the memory controller (or peripheral circuit) 105. In some embodiments, the voltage control circuit 116 can include a number of first headers and/or a number of first footers operatively coupled to the memory controller 105, and a number of second headers and/or a number of second footers operatively coupled to the memory array 120. Such headers/footers are generally configured to selectively connect a supply voltage (e.g., VDD, VDDM) or a reference voltage (e.g., a ground voltage) to the memory array 120 or the memory controller 105, based on a control, enable, or tracking signal. The headers/footers are sometimes referred to as power gating devices. In addition to the headers/footers, the voltage control circuit 116 can include various other circuit components (e.g., voltage boosters, voltage regulators, etc.) that are suitable for adjusting or otherwise controlling the supply voltage provided to the memory array 120 and/or the memory controller 105.

For example, the first header (e.g., a first PMOS transistor) can receive the first supply voltage (VDD) at one source/drain terminal of the first PMOS transistor and selectively provide the memory controller 105 with a virtual supply voltage (sometimes referred to as “VDDHD”) through the other source/drain terminal of the first PMOS transistor based on a signal fed into a gate terminal of the first PMOS transistor; and the second header (e.g., a second PMOS transistor) can receive the second supply voltage (VDDM) at one source/drain terminal of the second PMOS transistor and selectively provide the memory array 120 with another virtual supply voltage (sometimes referred to as “VDDAI”) through the other source/drain terminal of the second PMOS transistor based on a signal fed into a gate terminal of the second PMOS transistor.

In various embodiments of the present disclosure, the memory device 100, as disclosed herein, can be formed on both sides of a substrate. For example, the memory array 120 and the memory controller 105 of the memory device 100 can be formed as multiple transistors on a frontside of the substrate. On the frontside, a number of frontside metallization layers, each of which includes multiple frontside metal tracks, can be formed; and on a backside of the substrate, a number of backside metallization layers, each of which includes multiple backside metal tracks, can be formed. In general, the frontside metallization layers are referred to as M0 layer, M1 layer, M2 layer, M3 layer, M4 layer, and so on (in the order from the substrate to the topmost frontside metallization layer), and the backside metallization layers are referred to as BM0 layer, BM1 layer, BM2 layer, and so on (in the order from the substrate to the topmost backside metallization layer).

To maximize the routing flexibility for the frontside metal tracks and/or reduce capacitance coupling between the frontside metal tracks, some of the frontside metal tracks configured to carry the supply voltage or the ground voltage can be partially or fully removed from the frontside, and relocated to the backside. In one non-limiting example, the frontside metal tracks, configured to carry the second supply voltage VDDM, can be relocated from the M2 layer to the BM1 and/or BM2 layer. In another non-limiting example, the frontside metal tracks, configured to carry the virtual supply voltage VDDAI, can be relocated from the M2 layer to the BM1 and/or BM2 layer. In yet another non-limiting example, the frontside metal tracks, configured to carry the ground voltage VSS, the second supply voltage VDDM, and the virtual supply voltage VDDAI, can all be relocated from the M2 layer to the BM1 and/or BM2 layer.

Although, in FIG. 1, the memory device 100 is depicted as a part of a dual power rail system (e.g., with supply voltages VDD and VDDM powering the memory controller 105 and the memory array 120, respectively), it should be appreciated that the present disclosure is not limited to a memory device with the dual power rail system. For example, even with a single power rail system (e.g., with a single supply voltage VDD powering both the memory controller and memory array of a memory device), the memory device can include some of the frontside metal tracks, carrying the supply voltage VDD, to be relocated from the M2 layer to the BM1 and/or BM2 layer, while remaining within the scope of the present disclosure.

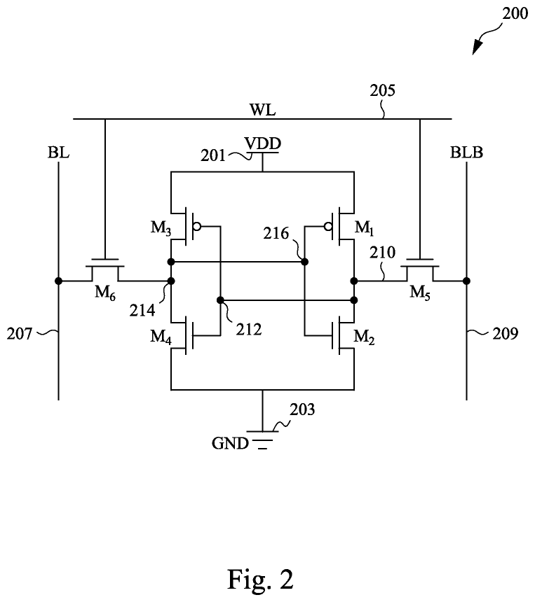

FIG. 2 illustrates a circuit diagram 200 of one example implementation of the memory cell 125 shown in FIG. 1 (hereinafter “memory cell 200”), in accordance with some embodiments. In the illustrative example of FIG. 2, the memory cell 200 includes a six-transistor (6T)-SRAM cell. In some other embodiments, the memory cell 200 may be implemented as any of a variety of other SRAM cells such as, for example, a two-transistor-two-resistor (2T-2R) SRAM cell, a four-transistor (4T)-SRAM cell, an eight-transistor (8T)-SRAM cell, a ten-transistor (10T)-SRAM cell, etc. Further, although the discussion of the current disclosure is directed to an SRAM cell, it is understood that other embodiments of the current disclosure can also be used in any of the memory cells such as, for example, dynamic random access (DRAM) memory cells.

As shown, the memory cell 200 includes 6 transistors: M1, M2, M3, M4, M5, and M6. The transistors M1 and M2 are formed as a first inverter and the transistors M3 and M4 are formed as a second inverter, wherein the first and second inverters are cross coupled to each other. For example, the first and second inverters are each coupled between a supply voltage 201 (e.g., VDDM in the dual power rail implementation) and a reference voltage 203 (e.g., VSS or a ground voltage). The first inverter (formed by the transistors M1 and M2) is coupled to the transistor M5, and the second inverter (formed by the transistors M3 and M4) is coupled to the transistor M6. In addition to being coupled to the first and second inverters, the transistors M6 and M5 are each coupled to a word line (WL) 205 and are coupled to a bit line (BL) 207 and a complementary bit line 209 (sometimes referred to as bit line bar or BLB), respectively.

In some embodiments, the transistors M1 and M3 are referred to as pull-up transistors of the memory cell 200 (hereinafter “pull-up transistor M1” and “pull-up transistor M3,” respectively); the transistors M2 and M4 are referred to as pull-down transistors of the memory cell 200 (hereinafter “pull-down transistor M2” and “pull-down transistor M4,” respectively); and the transistors M5 and M6 are referred to as access transistors of the memory cell 200 (hereinafter “access transistor M5” and “access transistor M6,” respectively). In some embodiments, the transistors M2, M4, M5, and M6 each includes an n-type metal-oxide-semiconductor (NMOS) transistor, and M1 and M3 each includes a p-type metal-oxide-semiconductor (PMOS) transistor. Although the illustrated embodiment of FIG. 2 shows that the transistors M1-M6 are either NMOS or PMOS transistors, any of a variety of transistors or devices that are suitable for use in a memory device may be implemented as at least one of the transistors M1-M6 such as, for example, a bipolar junction transistor (BJT), a high-electron-mobility transistor (HEMT), etc.

The access transistors M5 and M6 each has a gate terminal coupled to the word line WL 205. The gate terminals of the transistors M5 and M6 are configured to receive a pulse signal, through the word line WL 205, to allow or block an access of the memory cell 200 accordingly, which will be discussed in further detail below. The transistors M2 and M5 are coupled to each other at node 210 with the transistor M2's drain terminal and the transistor M5's source terminal. The node 210 is further coupled to a drain terminal of the transistor M1 and node 212. The transistors M4 and M6 are coupled to each other at node 214 with the transistor M4's drain terminal and the transistor M6's source terminal. The node 214 is further coupled to a drain terminal of the transistor M3 and node 116.

When a memory cell (e.g., the memory cell 200) stores a data bit, a first node of the bit cell is configured to be at a first logical state (either a logic 1 or a logic 0), and a second node of the bit cell is configured to be at a second logical state (either a logic 0 or a logic 1). The first and second logical states are complementary with each other. In some embodiments, the first logical state at the first node may represent the logical state of the data bit stored in the memory cell. For example, in the illustrated embodiment of FIG. 2, when the memory cell 200 store a data bit at a logic 1 state, the node 210 is configured to be at the logical 1 state, and the node 214 is configured to be at the logic 0 state.

To read the logical state of the data bit stored in the memory cell 200, the bit line BL 207 and bit line bar BLB 209 are pre-charged to VDDM (e.g., a logical high, e.g., using a capacitor to hold the charge). Then the word line WL 205 is asserted, or activated, by an assert signal to a logical high, which turns on the access transistors M5 and M6. Specifically, a rising edge of the assert signal is received at the gate terminals of the access transistors M5 and M6, respectively, so as to turn on the access transistors M5 and M6. Once the access transistors M5 and M6 are turned on, based on the logical state of the data bit, the pre-charged bit line BL 207 or bit line bar BLB 209 may start to be discharged. For example, when the memory cell 200 stores a logic 0, the node 214 (e.g., Q) may present a voltage corresponding to the logic 1, and the node 210 (e.g., Q bar) may present a voltage corresponding to the complementary logic 0. In response to the access transistors M5 and M6 being turned on, a discharge path, starting from the pre-charged bit line bar BLB 209, through the access transistor M5 and pull-down transistor M2, and to the ground voltage 203, may be provided. While the voltage level on the bit line bar BLB 209 is pulled down by such a discharge path, the pull-down transistor M4 may remain turned off. As such, the bit line BL 207 and the bit line bar BLB 209 may respectively present a voltage level to produce a large enough voltage difference between the bit line BL 207 and bit line bar BLB 209. Accordingly, a sensing amplifier, coupled to the bit line BL 207 and bit line bar BLB 209, can use a polarity of the voltage difference to determine whether the logical state of the data bit is a logic 1 or a logic 0.

To write the logical state of the data bit stored in the memory cell 200, the data to be written is applied to the bit line BL 207 and/or the bit line bar BLB 209. For example, the bit line bar BLB 209 is tied/shorted to OV, e.g., the ground voltage 203, with a low-impedance connection. Then, the word line WL 205 is asserted, or activated, by an assert signal to a logical high, which turns on the access transistors M5 and M6. Once the access transistors M5 and M6 are turned on, based on the logical state of the bit line bar BLB 209, the node 210 may start to be discharged. For example, before M5 and M6 are turned on, the bit line bar BLB 209 may present a voltage corresponding to the logic 0, and the node 210 may present a voltage corresponding to the complementary logic 1. In response to the access transistors M5 and M6 being turned on, a discharge path, starting from the node 210, through the access transistor M5 to the ground voltage 203, may be provided. Once the voltage level on the node 210 is pulled down below the Vth (threshold voltage) of the pull-down transistor M4, M4 may be turned off and M3 may be turned on, causing the node 214 to be pulled up to VDDM 201. Once node 214 is less than a Vth from VDD 201, M1 may be turned off and M2 may be turned off, causing the node 210 to be pulled down to the ground voltage 203. Then, when the word line WL 205 is de-asserted, the logical state applied to the bit line BL 207 and/or the bit line bar BLB 209 has been stored in the memory cell 200.

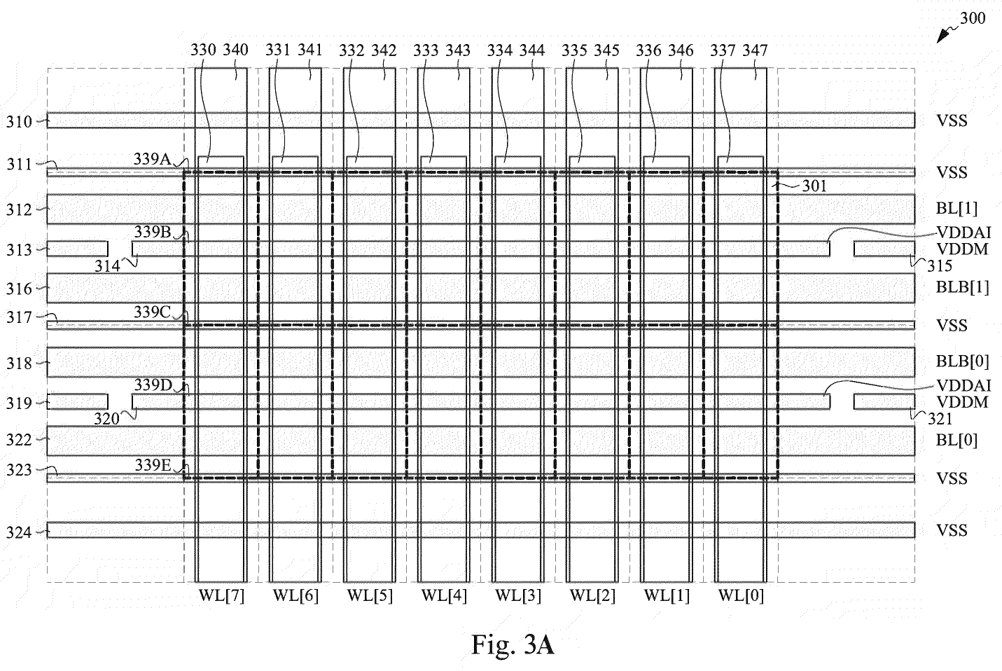

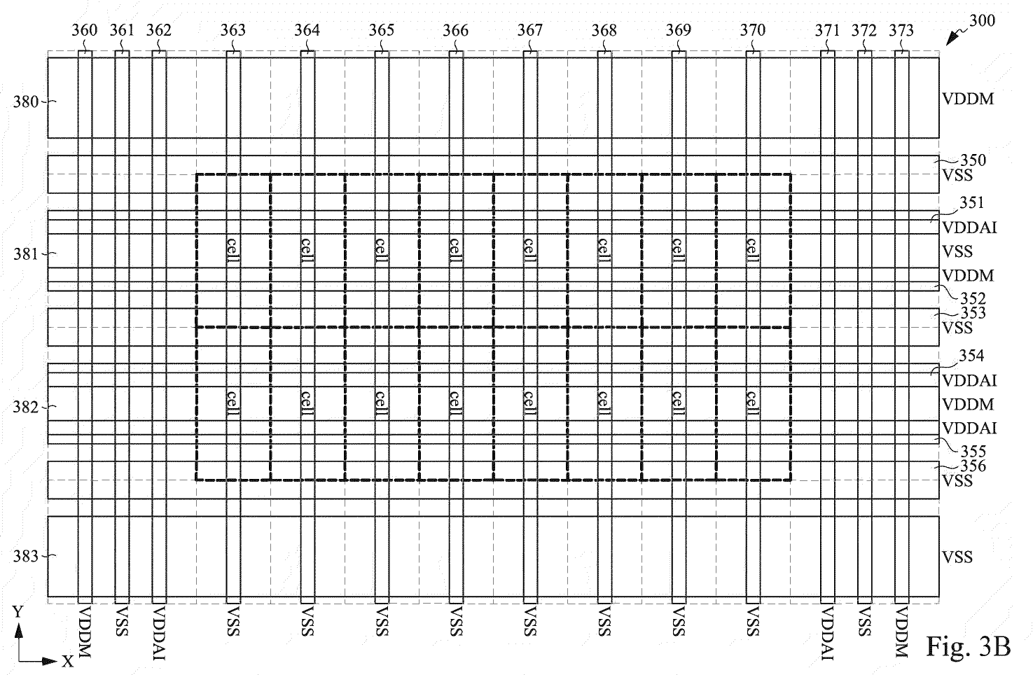

FIG. 3A and FIG. 3B collectively illustrate an example layout 300 that can be configured to form the disclosed memory device 100 that has a reduced number of frontside metal tracks carrying the ground voltage, the supply voltage, and/or the virtual supply voltage, in accordance with some embodiments. It should be appreciated that the layout 300 shown in FIGS. 3A-B has been simplified, and thus, the layout 300 can include any of various other components (e.g., patterns for forming respective structures) while remaining within the scope of the present disclosure.

Generally, the layout 300 includes a plural number of patterns configured to form respective structures such as, for example, frontside metal tracks, backside metal tracks, etc. Accordingly, such patterns of the disclosed layout are herein referred to as the structures to be formed, respectively, in the following discussion. For example, FIG. 3A may illustrate a top view of the layout 300 including a number of frontside metal tracks, and FIG. 3B may illustrate a top view of the layout 300 (flipped upside down) including a number of backside metal tracks, while each of FIG. 3A and FIG. 3B includes the memory cells formed on the frontside of a substrate.

Referring first to FIG. 3A, a number (e.g., 16) of memory cells 301 are formed or otherwise arranged in an area of a substrate. These 16 multiple memory cells 301 can at least partially form a memory array (e.g., 120 of FIG. 1) arranged over multiple rows and multiple columns. For example, in FIG. 3A, the memory cells 301 are arranged over 8 rows (e.g., extending in the Y-direction) and 2 columns (e.g., extending in the X-direction). Further, the memory cells 301 can each correspond to the 6T SRAM cell 200 shown in FIG. 2, and can each be implemented as a standard cell in the layout 300. In general semiconductor IC design, standard cell methodologies use standard cells as abstract representations of certain functions to integrate millions devices on a single chip.

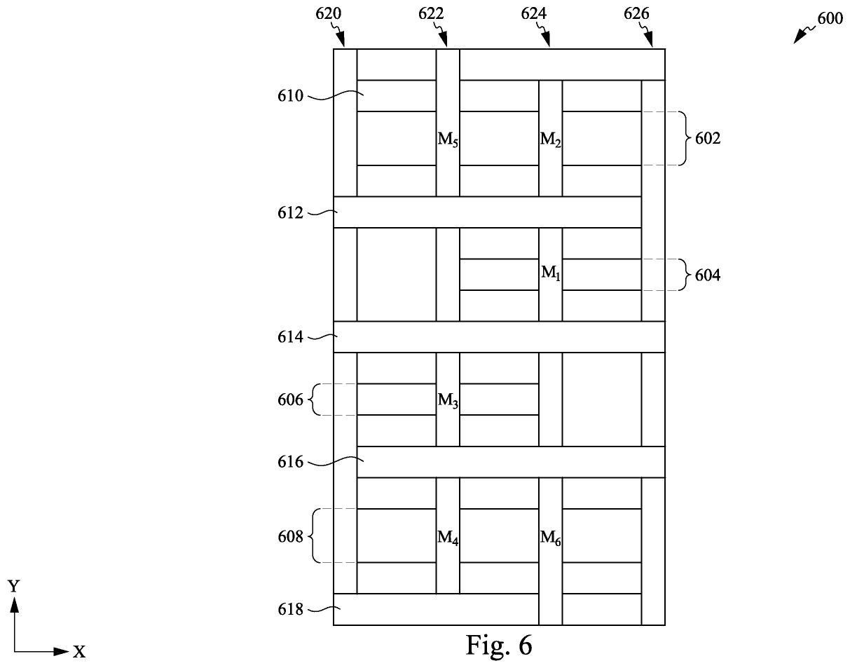

An example layout of the standard cell of each of these memory cells 301 will be discussed in further detail with respect to FIG. 6. In general, the memory cell 301, when implemented as a standard cell based on a 6T SRAM cell structure, can include a number of active regions extending along a first lateral direction and a number of gate structures extending along a second lateral direction. Each of these active regions can be overlaid by one or more of the gate structures, so as to form the 6 transistors, M1 to M6, that operatively form a 6T SRAM cell. It should be appreciated that as the memory cell 301 is implemented as other SRAM cell structure, the layout of the corresponding standard cell can vary accordingly.

Prior to, concurrently with, or subsequently to the transistors configured as the memory cells 301 being formed on the frontside of the substrate, a plural number of other transistors can also be formed on the frontside of the substrate. Such transistors can at least form as a memory controller (e.g., 105 of FIG. 1) operatively coupled to the memory cells 301. In some embodiments, these transistors can be physically formed around the area where the memory cells 301 are formed, and be implemented as various other standard cells (e.g., an AND gate, an OR gate, an XOR gate, a NOT gate, a NAND gate, a NOR gate, and an XNOR gate, and combinational logic circuits such as a multiplexer, a flip-flop, an adder, a counter, etc.), which are not shown for clarity purposes.

After the transistors operatively serving as the memory cells and the memory controller are formed, a number of frontside metallization layers can be formed over those transistors. Each of these frontside metallization layers can include (e.g., embed) a plural number of metal tracks in one or more dielectric layers (e.g., formed of an oxide material or a low-k dielectric material). As disclosed herein, a bottommost one of the frontside metallization layers is referred to as M0 layer, and the metal tracks formed in the M0 layer are referred to as M0 tracks. Over the M0 layer, M1 layer including a number of M1 tracks can be formed; over the M1 layer, M2 layer including a number of M2 tracks can be formed; over the M2 layer, M3 layer including a number of M3 tracks can be formed; and so on.

Referring still to FIG. 3A, the layout 300 includes a number of first patterns for forming M0 tracks 310, 311, 312, 313, 314, 315, 316, 317, 318, 319, 320, 321, 322, 323, and 324. The M0 tracks 310 to 324 can each extend along the X-direction, and each be configured to perform a certain function. For example, the M0 tracks 310-311, 317, and 323-324 can each be configured to carry the ground voltage VSS; the M0 tracks 322 and 318 can be configured as BL and BLB of a first column, BL[0] and BLB [0]; the M0 tracks 312 and 316 can be configured as BL and BLB of a second column, BL[1] and BLB [1]; the M0 tracks 313, 315, 319, and 321 can each be configured to carry the second supply voltage VDDM; and the M0 tracks 314 and 320 can each be configured to carry the virtual supply voltage VDDAI. Although not shown, it should be understood that each of these M0 tracks 310 to 324 can be electrically coupled to the underlying transistors through one or more via structures (sometimes referred to as VGs or VDs) and/or one or more contact structures (sometimes referred to as MDs).

Over the M0 tracks 310 to 324, the layout 300 includes a number of second patterns for forming M1 tracks 330, 331, 332, 333, 334, 335, 336, and 337. The M1 tracks 330 to 337 can each extend along the Y-direction, and each be configured to perform a certain function. For example, the M1 track 337 can be configured as the word line of a first row, WL[0]; the M1 track 336 can be configured as the word line of a second row, WL[1]; the M1 track 335 can be configured as the word line of a third row, WL[2]; the M1 track 334 can be configured as the word line of a fourth row, WL[3]; the M1 track 333 can be configured as the word line of a fifth row, WL[4]; the M1 track 332 can be configured as the word line of a sixth row, WL[5]; the M1 track 331 can be configured as the word line of a seventh row, WL[6]; and the M1 track 330 can be configured as the word line of an eighth row, WL[7].

Over the M1 tracks 330 to 337, there could be a number of patterns for forming M2 tracks. In the existing technologies, these M2 tracks, each of which is configured to carry one of the ground voltage VSS, the second supply voltage VDDM, or the virtual supply voltage VDDAI, are constrained to form on the frontside. However, according to the present disclosure, these M2 tracks are relocated from the frontside to the backside, which will be discussed in FIG. 3B. Such relocation of these M2 tracks that each carry a supply/reference voltage releases a significant amount of real estate in the M2 layer, which advantageously improves flexibility on placing other M2 tracks (e.g., 339A, 339B, 339C, 339D, 339E, etc.) that are each configured to carry a non-power signal. As disclosed herein, such a non-power signal generally refers to a signal not directly related (connected) to a supply voltage or a reference voltage and operatively communicated within a single circuit component (e.g., an SRAM cell) or across different circuit components (e.g., adjacent SRAM cells) such as, for example, the signal present on the bit line BL 207, bit line bar BLB 209, or word line WL 205. Further, without the M2 tracks carrying a supply/reference voltage formed, the capacitance coupling between the word lines formed in the M1 layer and the word lines formed in the M3 layer (discussed below) can be significantly reduced.

Over the M2 layer (or the M2 tracks 339A-E not configured for carrying a supply/reference voltage), the layout 300 include a number of third patterns for forming M3 tracks 340, 341, 342, 343, 344, 345, 346, and 347. The M3 tracks 340 to 347 can each extend along the Y-direction, and each be configured to perform a certain function. For example, the M3 track 347 can be configured as the word line of the first row, WL[0]; the M3 track 346 can be configured as the word line of the second row, WL[1]; the M3 track 345 can be configured as the word line of the third row, WL[2]; the M3 track 344 can be configured as the word line of the fourth row, WL[3]; the M3 track 343 can be configured as the word line of the fifth row, WL[4]; the M3 track 342 can be configured as the word line of the sixth row, WL[5]; the M3 track 341 can be configured as the word line of the seventh row, WL[6]; and the M3 track 340 can be configured as the word line of the eighth row, WL[7]. In some embodiments, none of these M3 tracks shown in FIG. 3A is configured to carry the ground voltage VSS, which is often constrained in the existing technologies. Such M3 tracks carrying the ground voltage VSS that are constrained in the existing technologies are relocated from the frontside to the backside, which can allow each of the word lines (e.g., the M3 tracks 340 to 347) to be formed wider (in the X-direction) or allow the word lines to space from each other with a wider spacing. With a wider width, each these word lines can advantageously have a lower resistance, and with a wider spacing, capacitance coupling between the adjacent word lines can be advantageously suppressed.

Below are several non-limiting examples compared with the existing memory devices. As a first non-limiting example, with a spacing between the adjacent M3 tracks unchanged as about 30 nanometers, the width of each of the M3 tracks 340 to 347 can increase from about 56 nanometers to about 66 nanometers. As such, a ratio of the width to the spacing may increase higher than 2. As a second non-limiting example, with a spacing between the adjacent M3 tracks increases by about 33%, the width of each of the M3 tracks 340 to 347 can increase by about 18%. As a third non-limiting example, with a spacing between the adjacent M3 tracks increases by about 40%, the width of each of the M3 tracks 340 to 347 can decrease by about 4%. As a fourth non-limiting example, with a spacing between the adjacent M3 tracks increases by about 47%, the width of each of the M3 tracks 340 to 347 can decrease by about 8%.

After the frontside metal tracks are formed, the substrate is flipped with a number of backside metallization layers formed on top of one another. Each of these backside metallization layers can include (e.g., embed) a plural number of metal tracks in one or more dielectric layers (e.g., formed of an oxide material or a low-k dielectric material). As disclosed herein, a bottommost one of the backside metallization layers is referred to as BM0 layer, and the metal tracks formed in the BM0 layer are referred to as BM0 tracks. Over the BM0 layer, BM1 layer including a number of BM1 tracks can be formed; over the BM1 layer, BM2 layer including a number of BM2 tracks can be formed; over the BM2 layer, BM3 layer including a number of BM3 tracks can be formed; and so on.

Referring next to FIG. 3B, with the memory cells 310 present as reference, the layout 300 includes a number of fourth patterns for forming BM0 tracks 350, 351, 352, 353, 354, 355, and 356. The BM0 tracks 350 to 356 can each extend along the X-direction, and each be configured to perform a certain function. For example, the BM0 tracks 350, 353, and 356 can each be configured to carry the ground voltage VSS; the M0 tracks 352 and 354 can each be configured to carry the second supply voltage VDDM; and the BM0 tracks 351 and 355 can each be configured to carry the virtual supply voltage VDDAI. Although not shown, it should be understood that each of these BM0 tracks 350 to 356 can be electrically coupled to the transistors through one or more via structures (sometimes referred to as BVs).

Over the BM0 tracks 350 to 356, the layout 300 includes a number of fifth patterns for forming BM1 tracks 360, 361, 362, 363, 364, 365, 366, 367, 368, 369, 370, 371, 372, and 373. The BM1 tracks 360 to 373 can each extend along the Y-direction, and each be configured to perform a certain function. For example, the BM1 tracks 361, 363-370, and 372 can each be configured to carry the ground voltage VSS; the BM1 tracks 360 and 373 can each be configured to carry the second supply voltage VDDM; and the BM1 tracks 362 and 371 can each be configured to carry the virtual supply voltage VDDAI.

Over the BM1 tracks 360 to 373, the layout 300 includes a number of sixth patterns for forming BM2 tracks 380, 381, 382, and 383. The BM2 tracks 380 to 383 can each extend along the X-direction, and each be configured to perform a certain function. For example, the BM2 tracks 380 and 382 can each be configured to carry the second supply voltage VDDM; and the BM2 tracks 381 and 383 can each be configured to carry the ground voltage VSS.

As indicated above, except for the M0 layer, none of the frontside metallization layers (e.g., M1 layer, M2 layer, M3 layer) includes a metal track carrying a supply or reference voltage, in accordance with the example layout 300 of FIGS. 3A-B. Such metal tracks configured to carry the supply/reference voltage are relocated to the backside. For example, the BM1 layer includes multiple metal tracks (e.g., 360, 373) configured to carry the second supply voltage VDDM, multiple metal tracks (e.g., 362, 371) configured to carry the virtual supply voltage VDDAI, and multiple metal tracks (e.g., 361, 363-370, 372) configured to carry the reference/ground voltage VSS. In another example, the BM2 layer includes multiple metal tracks (e.g., 380, 382) configured to carry the second supply voltage VDDM and multiple metal tracks (e.g., 381, 383) configured to carry the reference/ground voltage VSS.

It should be understood that the layout 300 of FIGS. 3A-B is merely one of various example layouts that can form a memory device with a reduced number of frontside metal tracks configured to carry a supply/reference voltage. Table below summarizes some of these alternative embodiments, which also include the arrangement of layout 300 as a reference. Each of the embodiments summarize where the metal tracks carrying VDDM/VDDAI/VSS are formed.

TABLE

| | Layout | Alternative | Alternative | Alternative | Alternative | Alternative |
|---|---|---|---|---|---|---|
| | 300 | Layout 1 | Layout 2 | Layout 3 | Layout 4 | Layout 5 |
| M3 | NA | NA | VDDM | VSS | VDDM | VSS |
| M2 | NA | VDDAI | VDDM, | VSS, VDDAI | VDDM | VSS |
| | | | VDDAI | | | |
| M1 | NA | VDDAI | VDDM, | VSS, VDDAI | VDDM | VSS |
| | | | VDDAI | | | |
| M0 | VDDM, | VDDM, | VDDM, | VDDM, | VDDM, | VDDM, |
| | VSS, | VSS, | VSS, | VSS, | VSS, | VSS, |
| | VDDAI | VDDAI | VDDAI | VDDAI | VDDAI | VDDAI |
| BM0 | VDDM, | VDDM, | VSS | VDDM | VSS, | VDDM, |
| | VSS, | VSS | | | VDDAI | VDDAI |
| | VDDAI | | | | | |
| BM1 | VDDM, | VDDM, | VSS | VDDM | VSS, | VDDM, |
| | VSS, | VSS | | | VDDAI | VDDAI |
| | VDDAI | | | | | |
| BM2 | VDDM, | VDDM, | VSS | VDDM | VSS | VDDM |
| | VSS | VSS | | | | |

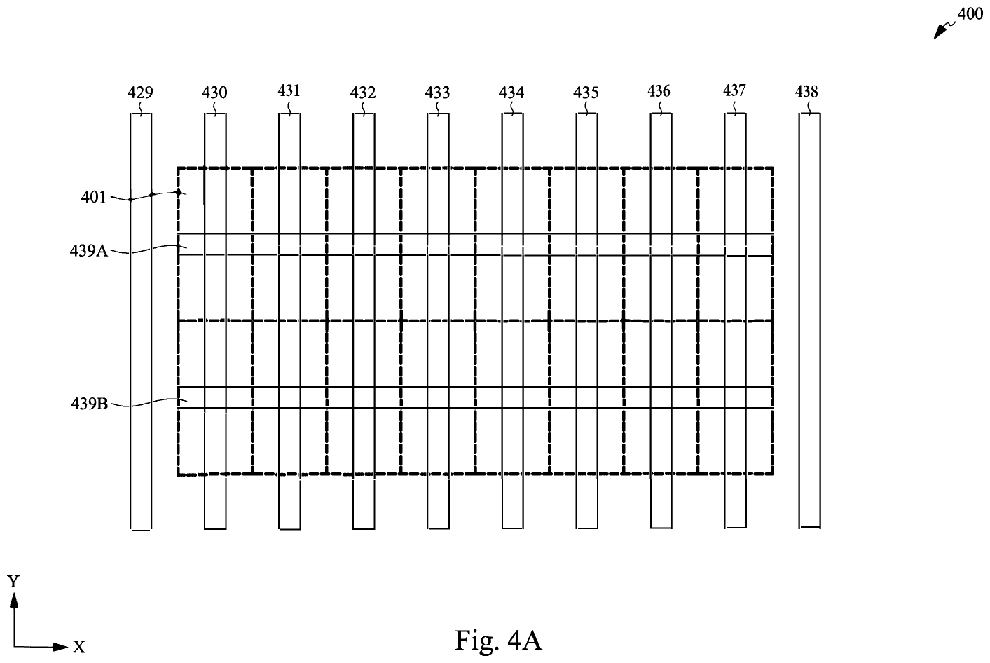

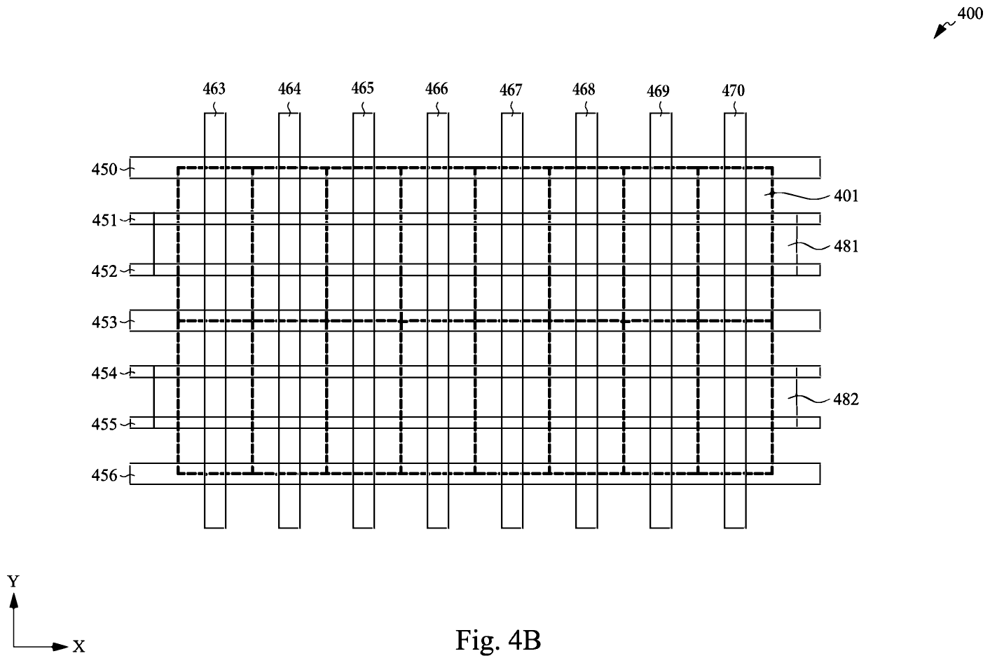

FIGS. 4A and 4B collectively illustrate a portion of the alternative layout 1 (hereinafter “layout 400”) that can be configured to form the disclosed memory device 100 with a reduced number of frontside metal tracks carrying the ground voltage, the supply voltage, and/or the virtual supply voltage, in accordance with some embodiments. Similar to the layout 300 of FIGS. 3A-B, a memory array with 16 memory cells 401 is shown in FIGS. 4A-B for reference.

In FIG. 4A, the layout 400 includes an M1 layer with M1 tracks 430, 431, 432, 433, 434, 435, 436, and 437 that are each configured as a word line and M1 tracks 429 and 438 that are each configured to carry VDDAI; and an M2 layer with M2 tracks 439A and 439B each configured to carry VDDAI. Despite not shown, the layout 400 can include an M0 layer with metal tracks configured to carry VDDM, VSS, and VDDAI and an M3 layer with no metal track configured to carry VDDM, VDDAI, or VSS, both of which are similar to the layout 300. In FIG. 4B, the layout 400 includes a BM0 layer with BM0 tracks 450, 453, and 456 that are each configured to carry VSS and BM0 tracks 451, 452, 454, and 455 that are each configured to carry VDDM; a BM1 layer with BM1 tracks 463, 464, 465, 466, 467, 468, 469, and 470 that are each configured to carry VSS; and a BM2 layer with BM2 track 481 configured to carry VSS and BM2 track 482 configured to carry VDDM. As such, in the M2 layer, there may only be metal tracks configured to carry VDDAI; and in the M3 layer, there may be no metal tracks configured to carry a supply or reference voltage.

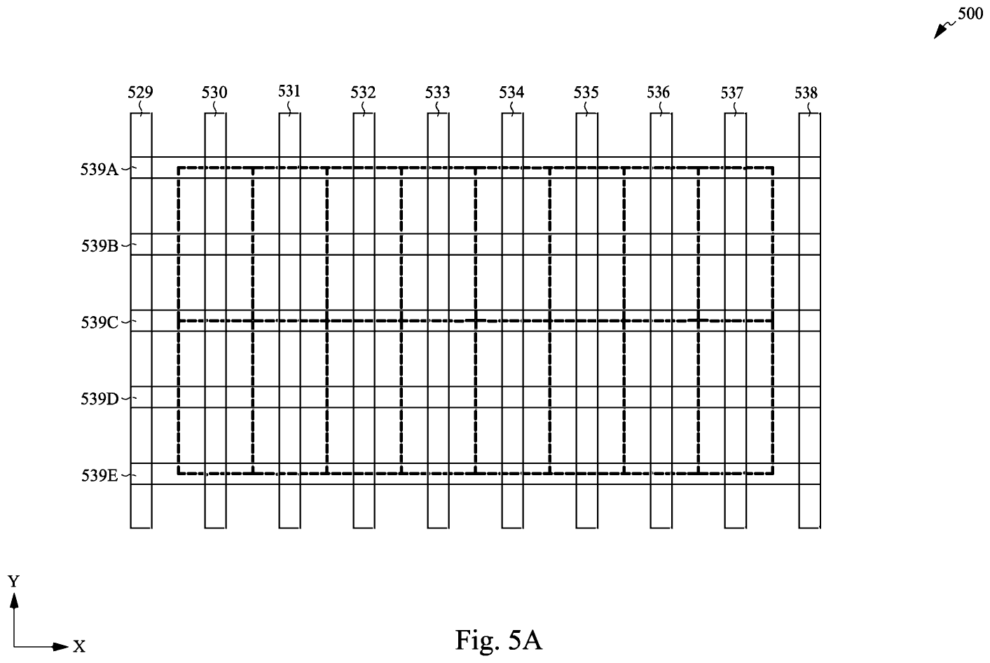

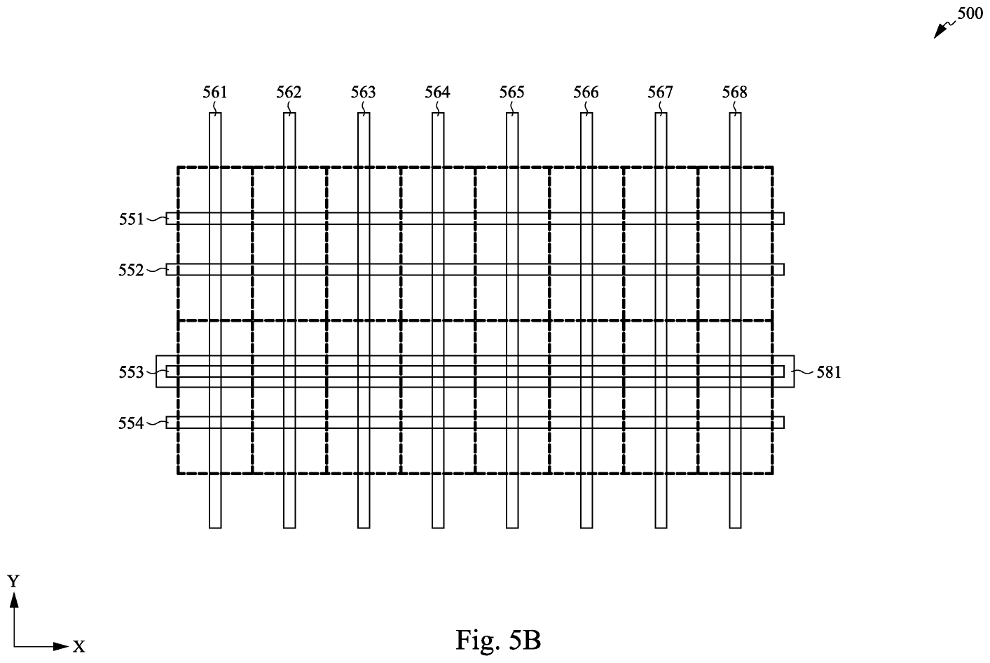

FIGS. 5A and 5B collectively illustrate a portion of the alternative layout 3 (hereinafter “layout 500”) that can be configured to form the disclosed memory device 100 with a reduced number of frontside metal tracks carrying the ground voltage, the supply voltage, and/or the virtual supply voltage, in accordance with some embodiments. Similar to the layout 300 of FIGS. 3A-B and layout 400 of FIGS. 4A-B, a memory array with 16 memory cells 501 is shown in FIGS. 5A-B for reference.

In FIG. 5A, the layout 500 includes an M1 layer with M1 tracks 530, 531, 532, 533, 534, 535, 536, and 537 that are each configured as a word line and M1 tracks 529 and 538 that are each configured to carry VDDAI or VSS; and an M2 layer with M2 tracks 539A, 539C, 539E that are each configured to carry VSS and M2 tracks 539B and 539D that are each configured to carry VDDAI. Despite not shown, the layout 400 can include an M0 layer with metal tracks configured to carry VDDM, VSS, and VDDAI (similar to the layout 300), and an M3 layer with multiple metal tracks configured to carry VSS. In FIG. 5B, the layout 500 includes a BM0 layer with BM0 tracks 551, 552, 553, and 554 that are each configured to carry VDDM; a BM1 layer with BM1 tracks 561, 562, 563, 564, 565, 566, 567, and 568 that are each configured to carry VDDM; and a BM2 layer with a BM2 track 581 configured to carry VDDM.

In such an embodiment (the alternative layout 500), the M2 tracks carrying VDDAI (e.g., 539B and 539D) and the M2 tracks carrying VSS (e.g., 539A, 539C, and 539E) can be alternately arranged along the Y-direction. For example, each of the memory cells 501 can have a first edge extending in the X-direction and overlaid by one of the M2 tracks 539A, 539C, or 539E, and a second edge extending in the X-direction and overlaid by another one of the M2 tracks 539A, 539C, or 539E, with one of the M2 tracks 539B or 539D traversing a middle part of the memory cell 501. Alternatively stated, a spacing between the M2 track carrying VSS and the M2 track carrying VDDAI (along the Y-direction) is equal to a half of a cell height of the memory cell 501.

FIG. 6 illustrates an example layout 600 configured to form a 6T SRAM cell (e.g., 200 of FIG. 2), in accordance with some embodiments. It should be appreciated that the layout 600 shown in FIG. 6 has been simplified, and thus, the layout 600 can include any of various other components (e.g., patterns for forming respective structures) while remaining within the scope of the present disclosure.

As shown, the layout 600 includes patterns for forming active regions 602, 604, 606, and 608, respectively. Each of the active regions 602 to 608 may be formed as a fin structure or a stack structure (with multiple first nanostructures and second nanostructure alternately stacked on top of one another) extending along the X-direction. The active regions 602 and 608 are formed in a first conduction type (e.g., n-type), and the active regions 604 and 606 are formed in a second conduction type (e.g., p-type). The layout 600 includes patterns for forming dummy regions 610, 612, 614, 616, and 618, each of which may also extend along the same lateral direction as the active regions 602 to 608. The layout 600 includes patterns for forming gate structures 620, 622, 624, and 626, each of which may extend along the Y-direction.

Each of the active regions 602 to 608 is straddled (or otherwise overlaid) by one or more of the gate structures 620-626 to define the respective channels of a number of transistors. On the opposite sides of each gate structure in the active region, a number of source/drain (e.g., epitaxial) structures can be formed. In some embodiments, the gate structures 620 to 626 can each be cut into a number of portions by the dummy regions 610 to 618. As such, the six transistors M1 to M6 of a 6T SRAM cell (e.g., 200) can be realized. For example, the access transistor M5 can be defined by the gate structure 622 and the source/drain structures formed in the active region 602; the pull-down transistor M2 can be defined by the gate structure 624 and the source/drain structures formed in the active region 602; the pull-up transistor M1 can be defined by the gate structure 624 and the source/drain structures formed in the active region 604; the pull-up transistor M3 can be defined by the gate structure 622 and the source/drain structures formed in the active region 606; the access transistor M6 can be defined by the gate structure 624 and the source/drain structures formed in the active region 608; and the pull-down transistor M4 can be defined by the gate structure 622 and the source/drain structures formed in the active region 608.

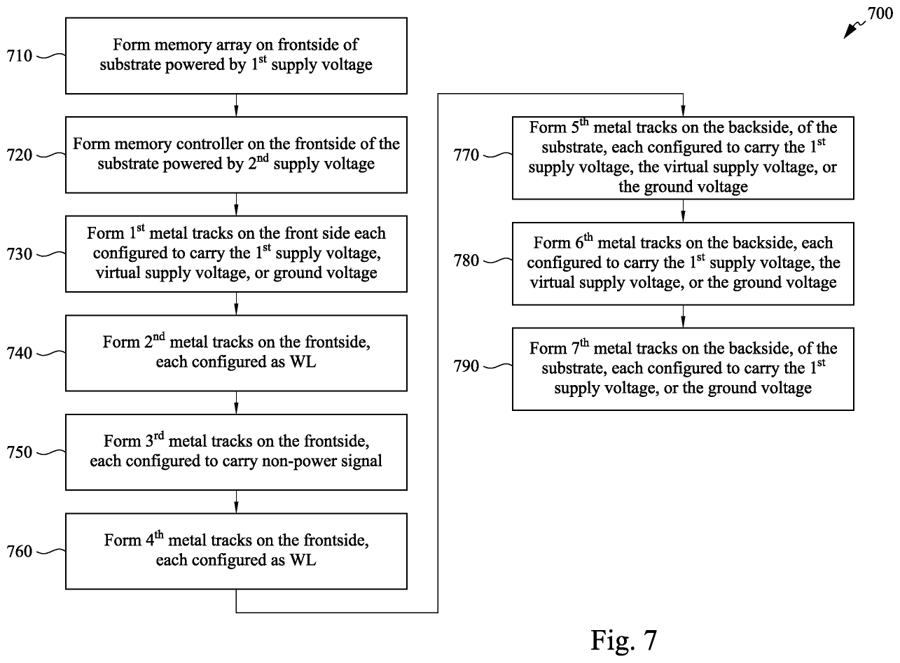

FIG. 7 illustrates a flow chart of a method 700 for fabricating a memory device, in accordance with some embodiments. The method 700 can be a part of a method for fabricating an integrated circuit. For example, operation of the method 700 can be configured for fabricating an integrated circuit based on the layout shown in FIGS. 3A-3B. Accordingly, the following discussion of the method 700 may sometimes refer to the above figures. It should be noted that the method 700 of FIG. 7 is merely an example, and is not intended to limit the present disclosure. Thus, it is understood that the order of the operations of the method 700 can be changed, for example, additional operations may be provided before, during, and after the method 700, and that some operations may only be described briefly herein.

The method 700 can start with operation 710 of forming a memory array on the frontside of a substrate. The memory array includes a number of memory cells (e.g., 301) powered by a first supply voltage (e.g., VDDM). The method 700 can proceed to operation 520 of forming a peripheral circuit (or memory controller) on the frontside. The memory controller is operatively coupled to the memory array and powered by a second supply voltage (e.g., VDD). The second supply voltage is different from the first supply voltage.

The method 700 can proceed to operation 730 of forming a first metallization layer on the frontside and over the memory array and the peripheral circuit, wherein the first metallization layer includes a plurality of first metal tracks. In some embodiments, each of the plurality of first metal tracks (e.g., M0 tracks 310 to 324) can extend along a first lateral direction and configured to carry the first supply voltage, a virtual supply voltage (e.g., VDDAI), or a ground voltage (e.g., VSS). The method 700 can proceed to operation 540 of forming a second metallization layer on the first side and over the first metallization layer, wherein the second metallization layer includes a plurality of second metal tracks. In some embodiments, each of the plurality of second metal tracks (e.g., M1 tracks 330 to 337) extends along a second lateral direction perpendicular to the first lateral direction and is configured as a word line operatively coupled to one or more of the plurality of memory cells. The method 700 can proceed to operation 750 of forming a third metallization layer on the first side and over the second metallization layer, wherein the third metallization layer includes a plurality of third metal tracks. In some embodiments, each of the plurality of third metal tracks (e.g., M2 tracks not shown in FIG. 3A) extends along the first lateral direction and is configured to only carry a non-power signal instead of carrying the first supply voltage. The method 700 can proceed to operation 760 of forming a fourth metallization layer on the first side and over the third metallization layer, wherein the fourth metallization layer includes a plurality of fourth metal tracks. In some embodiments, each of the plurality of fourth metal tracks (e.g., M3 tracks 340 to 347) extending along the second lateral direction and configured only as the word line.

The method 700 can proceed to operation 770 of forming a fifth metallization layer on a second side of the substrate, wherein the fifth metallization layer includes a plurality of fifth metal tracks. In some embodiments, each of the plurality of fifth metal tracks (e.g., BM0 tracks 350 to 356) extends along the first lateral direction and is configured to carry the first supply voltage VDDM, the virtual supply voltage VDDAI, or the ground voltage VSS. The method 700 can proceed to operation 780 of forming a sixth metallization layer on the second side and over the fifth metallization layer, wherein the sixth metallization layer includes a plurality of sixth metal tracks. In some embodiments, each of the plurality of sixth metal tracks (e.g., BM1 tracks 260 to 373) extends along the second lateral direction and is configured to carry the first supply voltage VDDM, the virtual supply voltage VDDAI, or the ground voltage VSS. The method 700 can proceed to operation 790 of forming a seventh metallization layer on the second side of the substrate, wherein the seventh metallization layer includes a plurality of seventh metal tracks. In some embodiments, each of the plurality of seventh metal tracks (e.g., BM2 tracks 380 to 383) extends along the first lateral direction and is configured to carry the first supply voltage VDDM or the ground voltage VSS.

In one aspect of the present disclosure, a memory device is disclosed. The memory device includes a plurality of memory cells physically formed on a first side of a substrate; a peripheral circuit operatively coupled to the plurality of memory cells and physically formed on the first side of the substrate; a first metallization layer physically formed on the first side of the substrate and including a plurality of first metal tracks, each of the plurality of first metal tracks extending along a first lateral direction and configured to carry a supply voltage or a ground voltage, the first supply voltage configured to power the plurality of memory cells; a second metallization layer physically formed on the first side of the substrate and including a plurality of second metal tracks, each of the plurality of second metal tracks extending along a second lateral direction and configured as a word line operatively coupled to one or more of the plurality of memory cells; a third metallization layer physically formed on the first side of the substrate and including a plurality of third metal tracks, each of the plurality of third metal tracks extending along the first lateral direction, at least one of the plurality of third metal tracks configured to only carry a non-power signal instead of carrying the supply voltage; a fourth metallization layer physically formed on the first side of the substrate and including a plurality of fourth metal tracks, each of the plurality of fourth metal tracks extending along the second lateral direction and configured only as the word line; a fifth metallization layer physically formed on a second side of the substrate and including a plurality of fifth metal tracks, each of the plurality of fifth metal tracks extending along the first lateral direction and configured to carry the supply voltage or the ground voltage; and a sixth metallization layer physically formed on the second side of the substrate and including a plurality of sixth metal tracks, each of the plurality of sixth metal tracks extending along the second lateral direction and configured to carry the supply voltage or the ground voltage.

In another aspect of the present disclosure, a memory device is disclosed. The memory device includes a memory cell powered by a first supply voltage; a peripheral circuit operatively coupled to the memory cell and powered by a second supply voltage; a first metal track and a second metal track disposed in a first one of a plurality of frontside metallization layers and extending in a first lateral direction, the first metal track and the second metal track configured to carry the first supply voltage and a ground voltage, respectively, the supply voltage being provided to power the memory cell; a third metal track disposed in a second one of the plurality of frontside metallization layers and extending in a second lateral direction, the third metal track configured as a word line operatively coupled to the memory cell; a fourth metal track and a fifth metal track disposed in a third one of the plurality of frontside metallization layers and extending in the first lateral direction, the fourth metal track and the fifth metal track configured to carry a virtual supply voltage and the ground voltage, respectively, the virtual supply voltage being selectively provided to power the memory cell; a sixth metal track disposed in a first one of a plurality of backside metallization layers and extending in the first lateral direction, the sixth metal track configured to carry the first supply voltage; and a seventh metal track disposed in a second one of the plurality of backside metallization layers and extending in the second lateral direction, the seventh metal track configured to carry the first supply voltage.

In yet another aspect of the present disclosure, a method for forming a memory device is disclosed. The method includes forming a memory array on a first side of a substrate, the memory array including a plurality of memory cells powered by a first supply voltage. The method includes forming a peripheral circuit on the first side of the substrate, the peripheral circuit operatively coupled to the memory array and powered by a second supply voltage different from the first supply voltage. The method includes forming a first metallization layer on the first side and over the memory array and the peripheral circuit, the first metallization layer including a plurality of first metal tracks, each of the plurality of first metal tracks extending along a first lateral direction and configured to carry the first supply voltage or a ground voltage. The method includes forming a second metallization layer on the first side and over the first metallization layer, the second metallization layer including a plurality of second metal tracks, each of the plurality of second metal tracks extending along a second lateral direction and configured as a word line operatively coupled to one or more of the plurality of memory cells. The method includes forming a third metallization layer on the first side and over the second metallization layer, the third metallization layer including a plurality of third metal tracks, each of the plurality of third metal tracks extending along the first lateral direction and configured to only carry a non-power signal instead of carrying the first supply voltage. The method includes forming a fourth metallization layer on the first side and over the third metallization layer, the fourth metallization layer including a plurality of fourth metal tracks, each of the plurality of fourth metal tracks extending along the second lateral direction and configured only as the word line. The method includes forming a fifth metallization layer on a second side of the substrate, the fifth metallization layer including a plurality of fifth metal tracks, each of the plurality of fifth metal tracks extending along the first lateral direction and configured to carry the first supply voltage or the ground voltage. The method includes forming a sixth metallization layer on the second side and over the fifth metallization layer, the sixth metallization layer including a plurality of sixth metal tracks, each of the plurality of sixth metal tracks extending along the second lateral direction and configured to carry the first supply voltage or the ground voltage.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a plurality of memory cells physically formed on a first side of a substrate;
a peripheral circuit operatively coupled to the plurality of memory cells and physically formed on the first side of the substrate;
a first metallization layer physically formed on the first side of the substrate and including a plurality of first metal tracks, each of the plurality of first metal tracks extending along a first lateral direction and configured to carry a supply voltage or a ground voltage, the supply voltage configured to power the plurality of memory cells;
a second metallization layer physically formed on the first side of the substrate and including a plurality of second metal tracks, each of the plurality of second metal tracks extending along a second lateral direction and configured as a word line operatively coupled to one or more of the plurality of memory cells;
a third metallization layer physically formed on the first side of the substrate and including a plurality of third metal tracks, each of the plurality of third metal tracks extending along the first lateral direction, at least one of the plurality of third metal tracks configured to only carry a non-power signal instead of carrying the supply voltage;
a fourth metallization layer physically formed on the first side of the substrate and including a plurality of fourth metal tracks, each of the plurality of fourth metal tracks extending along the second lateral direction and configured only as the word line;
a fifth metallization layer physically formed on a second side of the substrate and including a plurality of fifth metal tracks, each of the plurality of fifth metal tracks extending along the first lateral direction and configured to carry the supply voltage or the ground voltage; and
a sixth metallization layer physically formed on the second side of the substrate and including a plurality of sixth metal tracks, each of the plurality of sixth metal tracks extending along the second lateral direction and configured to carry the supply voltage or the ground voltage.

2. The memory device of claim 1, further comprising a power switch configured to receive the supply voltage and selectively provide a virtual supply voltage to the plurality of memory cells.

3. The memory device of claim 2, wherein each of the memory cells is overlaid by one of the third metal tracks that is configured to carry the virtual supply voltage.

4. The memory device of claim 3, wherein another one of the third metal tracks configured to carry the ground voltage and yet another one of the third metal tracks configured to carry the virtual supply voltage are spaced from each other with a distance along the second lateral direction.

5. The memory device of claim 4, wherein the distance is equal to one half of a cell height of each of the memory cells.

6. The memory device of claim 4, wherein no other third metal track is interposed between the another one of the third metal tracks configured to carry the ground voltage and the yet another one of the third metal tracks configured to carry the virtual supply voltage.

7. The memory device of claim 1, wherein each of the memory cells is free from being overlaid by any metal track that is formed in the third metallization layer and configured to carry the supply voltage.

8. The memory device of claim 1, wherein each of the plurality of memory cells includes a Static Random Access Memory cell.

9. The memory device of claim 1, wherein none of the plurality of fourth metal tracks is configured to carry the ground voltage.

10. The memory device of claim 1, wherein a ratio of a width of each of the plurality of fourth metal tracks along the first lateral direction to a spacing between adjacent ones of the plurality of fourth metal tracks is equal to or larger than 2.

11. The memory device of claim 1, wherein, on the first side, the fourth metallization layer is disposed over the third metallization layer, which is disposed over the second metallization layer, which is disposed over the first metallization layer, and wherein, on the second side, the sixth metallization layer is disposed over the fifth metallization layer.

12. A memory device, comprising:
a memory cell powered by a first supply voltage;
a peripheral circuit operatively coupled to the memory cell and powered by a second supply voltage;
a first metal track and a second metal track disposed in a first one of a plurality of frontside metallization layers and extending in a first lateral direction, the first metal track and the second metal track configured to carry the first supply voltage and a ground voltage, respectively, the first supply voltage being provided to power the memory cell;
a third metal track disposed in a second one of the plurality of frontside metallization layers and extending in a second lateral direction, the third metal track configured as a word line operatively coupled to the memory cell;
a fourth metal track and a fifth metal track disposed in a third one of the plurality of frontside metallization layers and extending in the first lateral direction, the fourth metal track and the fifth metal track configured to carry a virtual supply voltage and the ground voltage, respectively, the virtual supply voltage being selectively provided to power the memory cell;
a sixth metal track disposed in a first one of a plurality of backside metallization layers and extending in the first lateral direction, the sixth metal track configured to carry the first supply voltage; and
a seventh metal track disposed in a second one of the plurality of backside metallization layers and extending in the second lateral direction, the seventh metal track configured to carry the first supply voltage.

13. The memory device of claim 12, further comprising a power switch configured to receive the first supply voltage and selectively provide the virtual supply voltage to the memory cell.

14. The memory device of claim 12, wherein the memory cell and the peripheral circuit are formed along a major surface of a substrate, and wherein the plurality of frontside metallization layers and the plurality of backside metallization layers are formed on opposite sides of the substrate, respectively.

15. The memory device of claim 12, wherein no other metal track in the third frontside metallization layer is interposed between the fourth metal track and the fifth metal track.

16. The memory device of claim 15, wherein the fourth metal track and the fifth metal track are spaced from each other with a distance in the second lateral direction, and wherein the distance is equal to one half of a cell height of the memory cell.

17. The memory device of claim 12, wherein the first supply voltage and the second supply voltage are different from each other.

18. A method for forming a memory device, comprising:
forming a memory array on a first side of a substrate, the memory array including a plurality of memory cells powered by a first supply voltage;
forming a peripheral circuit on the first side of the substrate, the peripheral circuit operatively coupled to the memory array and powered by a second supply voltage different from the first supply voltage;
forming a first metallization layer on the first side and over the memory array and the peripheral circuit, the first metallization layer including a plurality of first metal tracks, each of the plurality of first metal tracks extending along a first lateral direction and configured to carry the first supply voltage or a ground voltage;
forming a second metallization layer on the first side and over the first metallization layer, the second metallization layer including a plurality of second metal tracks, each of the plurality of second metal tracks extending along a second lateral direction and configured as a word line operatively coupled to one or more of the plurality of memory cells;
forming a third metallization layer on the first side and over the second metallization layer, the third metallization layer including a plurality of third metal tracks, each of the plurality of third metal tracks extending along the first lateral direction and configured to only carry a non-power signal instead of carrying the first supply voltage;
forming a fourth metallization layer on the first side and over the third metallization layer, the fourth metallization layer including a plurality of fourth metal tracks, each of the plurality of fourth metal tracks extending along the second lateral direction and configured only as the word line;
forming a fifth metallization layer on a second side of the substrate, the fifth metallization layer including a plurality of fifth metal tracks, each of the plurality of fifth metal tracks extending along the first lateral direction and configured to carry the first supply voltage or the ground voltage; and
forming a sixth metallization layer on the second side and over the fifth metallization layer, the sixth metallization layer including a plurality of sixth metal tracks, each of the plurality of sixth metal tracks extending along the second lateral direction and configured to carry the first supply voltage or the ground voltage.

19. The method of claim 18, wherein a ratio of a width of each of the plurality of fourth metal tracks along the first lateral direction to a spacing between adjacent ones of the plurality of fourth metal tracks is equal to or larger than 2.

20. The method of claim 18, wherein each of the plurality of memory cells includes a Static Random Access Memory cell.
